(19) United States
(12) Patent Application Publication
(10) Pub. No.: US 2026/0353600 A1
(43) Pub. Date: Nov. 5, 2026

(54) ADAPTER FOR COOLING AN ELECTRONIC EQUIPMENT

(71) Applicant: Vertiv Corporation, Westerville, OH (US)

(72) Inventors: Akshay D. Shah, Pune (IN); Dilesh Arvind Raut, Pune (IN)

(21) Appl. No.: 19/667,214

(22) Filed: May 4, 2026

(30) Foreign Application Priority Data
May 5, 2025 (IN) 202511043499

(51) Int. Cl. H05K 7/20

(52) U.S. Cl. CPC H05K 7/20263; H05K 7/20145; H05K 7/20909

(57) ABSTRACT

An adapter for an electronic equipment is disclosed. The adapter includes a housing having an air intake region and an air outlet region, and one or more fluid conduits positioned to form a mesh between the intake and outlet regions. The adapter includes an input port and an output port for circulating a cooling fluid through the fluid conduits. The cooling fluid absorbs heat from air flowing through the adapter before entering the air vents of the electronic equipment. The fluid conduits may be interconnected or discrete and may be shaped as pipes or fins. The adapter is mountable on a front facia of the electronic equipment to enable modular, non-intrusive cooling enhancement.

### CROSS-REFERENCE TO RELATED APPLICATIONS

This application claims priority to Indian Provisional Application No. 202511043499, filed May 05, 2025, which is hereby incorporated by reference in its entirety.

### TECHNICAL FIELD

The present invention generally relates to thermal management in electronic systems. More specifically, the present invention is related to cooling enhancements for air vents used in power electronic equipment to maintain optimal thermal conditions.

### BACKGROUND

Power electronic systems such as rectifiers, converters, and power supply units form a foundational part of modern electrical infrastructure across industrial automation, telecommunications, data centers, and energy distribution networks. These systems typically operate continuously while processing substantial electrical loads, resulting in generation of considerable heat during normal operation. Effective thermal management is therefore essential to maintain operational stability, reliability, and longevity of such systems.

To prevent overheating, most power electronic systems employ air-based cooling mechanisms. A commonly adopted approach includes a fan-driven air intake system positioned at an air intake region of the equipment enclosure, configured to draw ambient air across heat-generating components. Such fan-driven air vents are widely used due to their structural simplicity, cost-effectiveness, and compatibility with modular or rack-mounted configurations. The cooling performance of these systems is primarily dependent upon the temperature, flow rate, and quality of the incoming ambient air.

Although requirement for thermal management is particularly significant in power electronic systems, similar air-based cooling architectures are also employed in other air-cooled enclosures housing electronic or electromechanical equipment. Examples include battery backup units, edge computing modules, industrial automation control panels, and telecommunications base station cabinets. In such configurations, intake air serves as the principal or sole medium of thermal regulation.

### SUMMARY OF THE INVENTION

This summary is provided to introduce aspects related to an adapter for cooling an electronic equipment. The adapter is configured to enhance cooling performance by reducing temperature of intake air before it enters equipment enclosure. The adapter includes a housing with fluid conduits through which a cooling fluid circulates to absorb heat from incoming air, thereby improving thermal management efficiency.

An adapter for an electronic equipment is disclosed. The adapter includes a housing having an air intake region and an air outlet region. The housing comprises one or more fluid conduits positioned to form a mesh between the air intake region and the air outlet region. Further the adapter includes at least one input port to introduce cooling fluid into the one or more fluid conduits and at least one outlet port to discharge the cooling fluid from the one or more fluid conduits.

The cooling fluid absorbs heat from air passing through the air intake region to the air outlet region of the housing. Further, the adapter is mountable on a front facia of the electronic equipment having one or more air vents, reducing temperature of the air passing through the air intake region and air outlet region of the housing into the air vents of the electronic equipment.

A cooling system for an electronic equipment is also disclosed. The cooling system includes electronic equipment having an enclosure with one or more air vents on a front facia and at least one inbuilt fan system configured to draw air through the one or more air vents. The system further includes an adapter mounted on the front facia of the electronic equipment. The adapter includes a housing having an air intake region and an air outlet region aligned with the one or more air vents, with the housing comprising one or more fluid conduits positioned to form a mesh between the air intake region and the air outlet region. The adapter further includes at least one input port to introduce cooling fluid into the one or more fluid conduits and at least one outlet port to discharge the cooling fluid from the one or more fluid conduits. The cooling fluid absorbs heat from air passing through the air intake region to the air outlet region of the housing before the air enters the one or more air vents of the electronic equipment,

A method of cooling electronic equipment is disclosed. The method includes mounting an adapter on a front facia of the electronic equipment with the adapter comprising a housing having an air intake region and an air outlet region aligned with one or more air vents of the electronic equipment and the housing comprising one or more fluid conduits positioned to form a mesh between the air intake region and the air outlet region. The method further includes circulating a cooling fluid through the one or more fluid conduits via at least one input port and at least one outlet port of the adapter. The method further includes drawing air through the air intake region of the housing using an inbuilt fan system of the electronic equipment. The method further includes absorbing heat from the air passing through the air intake region to the air outlet region of the housing using the cooling fluid, thereby reducing temperature of the air before the air enters the one or more air vents of the electronic equipment.

Other aspects and advantages of the invention will become apparent from the following description, taken in conjunction with the accompanying drawings, illustrating by way of example the principles of the invention.

### BRIEF DESCRIPTION OF THE DRAWINGS

The accompanying figures of the drawing, which are included to provide a further understanding of general aspects of the system/method, are incorporated in and constitute a part of this specification. These illustrative aspects of the system/method, and together with the detailed description, explain the principles of the system. No attempt is made to show structural details in more detail than is necessary for a fundamental understanding of the system and various ways in which it is practiced. The following figures of the drawing include:

FIG. 1A illustrates a disassembled view of an electronic equipment and an adapter for cooling the electronic equipment;

FIG. 1B illustrates an assembled view of the electronic equipment and the adapter for cooling the electronic equipment;

FIG. 2A illustrates a perspective view of the adapter and an expanded view of pipe-structured fluid conduits of the adapter;

FIG. 2B illustrates a perspective view of the adapter and an expanded view of fin-structured fluid conduits of the adapter; and

FIG. 3 illustrates an assembled view of the electronic equipment and another adapter for cooling the electronic equipment, and an expanded view of the another adapter.

In the appended figures, similar components and/or features may have the same numerical reference label. Further, various components of the same type may be distinguished by following the reference label with a letter. If only the first numerical reference label is used in the specification, the description is applicable to any one of the similar components and/or features having the same first numerical reference label irrespective of the suffix.

### DESCRIPTION OF THE INVENTION

Illustrative embodiments are described with reference to the accompanying drawings. Wherever convenient, the same reference numbers are used throughout the drawings to refer to the same or like parts. While examples and features of disclosed principles are described herein, modifications, adaptations, and other implementations are possible without departing from the spirit and scope of the disclosed embodiments. It is intended that the following detailed description be considered as exemplary only, with the true scope and spirit being indicated by the following claims.

Conventional fan-driven air intake systems rely substantially on ambient environmental conditions, which are often suboptimal. In many deployment environments, including densely packed control rooms, outdoor telecommunications shelters, and enclosed server cabinets, the available intake air may be warm, stagnant, dust-laden, or humid. These adverse air conditions directly reduce the effectiveness of heat dissipation.

Reduced cooling efficiency leads to elevated internal temperatures within the enclosure, formation of localized thermal hotspots, and increased thermal stress on sensitive components. Over time, such thermal stress can accelerate component degradation, reduce system reliability, and increase maintenance requirements. In extreme operating scenarios, elevated temperatures may necessitate forced derating of power modules or may even result in premature system failure.

Heating problem is further exacerbated by increasing power densities in modern electronic equipment, while enclosure sizes remain constrained due to industry standards and installation limitations. Despite the critical role of intake air in maintaining acceptable thermal conditions, conventional air-vent and fan-driven cooling systems typically do not incorporate mechanisms to condition, regulate, or enhance the incoming air prior to its interaction with internal components. Consequently, there exists a need for an improved cooling mechanism for air-vent or fan-driven cooling systems that enhances thermal performance, improves reliability, extends equipment lifespan, and reduces maintenance burden.

The present invention solves the challenges faced by existing solutions by providing a modular, externally mountable adapter that conditions intake air (airflow) of electronic equipment using a cooling fluid-based heat exchange mechanism. The adapter comprises a housing having an air passage through which intake air flows before entering the electronic equipment. Embedded within the housing is a network of fluid conduits, through which a cooling fluid circulates. As air passes over the fluid conduits, heat is absorbed from the airflow, thereby reducing the temperature of the intake air before it reaches the sensitive internal components of the equipment.

By enabling localized air cooling at the point of intake, the present invention offers an efficient and easily deployable solution to mitigate thermal hotspots, extend component life, and improve the thermal margin of power electronic systems and other air-cooled enclosures. Its modular design supports easy attachment and detachment, making it suitable for both new installations and field-deployed systems.

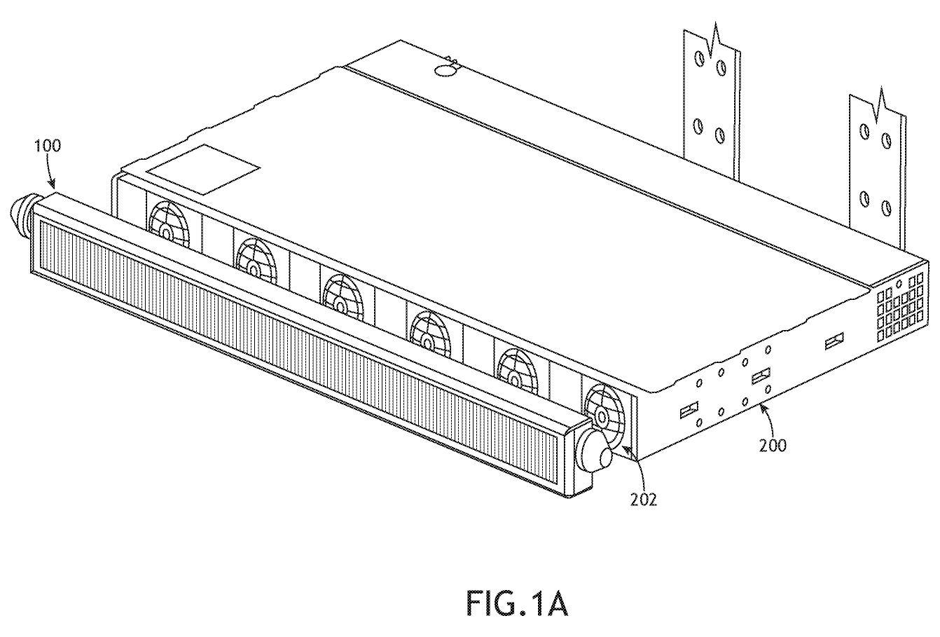

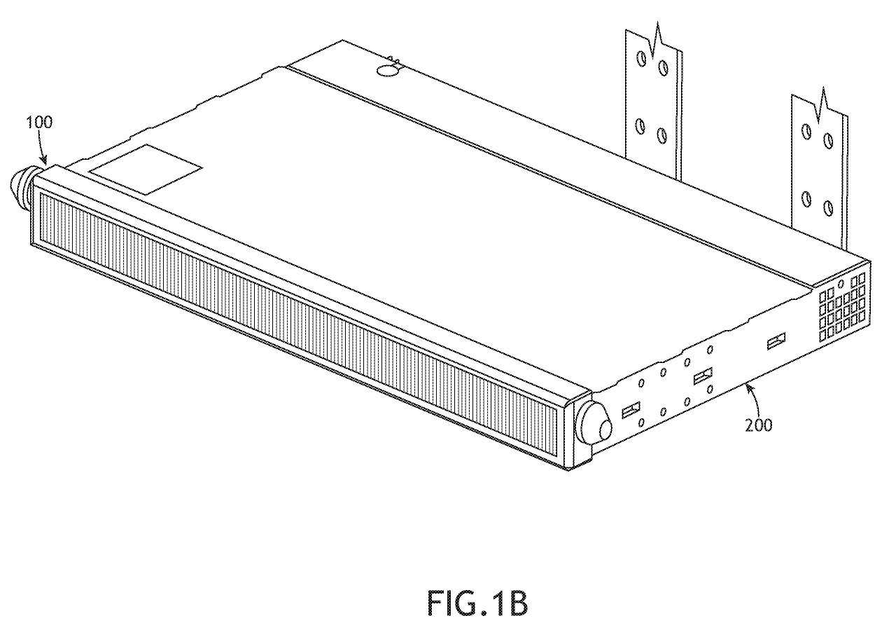

FIG. 1A illustrates a disassembled view of an electronic equipment 200 and an adapter 100 for cooling the electronic equipment 200. The electronic equipment 200 may include, but is not limited to, power electronic devices such as rectifiers, DC-DC converters, inverters, power supply units (PSUs), and battery backup modules. Further, the electronic equipment 200 may include uninterruptible power supplies (UPS), power distribution units (PDUs), and other devices commonly used in telecommunications, industrial automation, or data center environments, that generate heat in operation.

Additionally, the electronic equipment 200 may also include network hardware such as servers, routers, switches, control panels in industrial systems, edge computing enclosures or base station cabinets in outdoor or remote installations. More generally, “electronic equipment” as used hereinafter may refer to any enclosed system or device that generates heat during operation, incorporates one or more air vents for the purpose of cooling internal components using airflow, and includes at least one inbuilt fan system configured to draw air through the one or more air vents.

The adapter 100 may be configured to absorb heat from the airflow being used to cool the electronic equipment 200. Thus, the adapter 100 may be applied to any equipment where conditioning the airflow can enhance thermal management, reduce internal hotspots, and improve performance and reliability of the electronic equipment 200.

FIG. 1B illustrates an assembled view of the electronic equipment 200 and the adapter 100 for cooling the electronic equipment 200. The adapter 100 may be positioned externally with respect to the electronic equipment 200, such that the adapter 100 may align with the air vents 202 located on the front facia of the electronic equipment 200. Retro-fitting arrangement of the adapter 100 enables a modular integration with the electronic equipment 200 without requiring internal modifications to the electronic equipment 200.

The adapter 100 may be retrofitted to the electronic equipment 200 through a variety of attachment mechanisms, providing flexibility for integration across different equipment designs, form factors, and operational environments. The adapter 100 may include one or more snap-fit connectors that align with pre-existing slots, grooves, or anchoring features on the front facia of the electronic equipment 200. In one implementation, the adapter 100 may be fastened using one or more of spring-loaded screws, threaded bolts, and panel mount clips, allowing for a mechanically stable connection that can withstand vibration, movement, or exposure to dynamic airflow conditions. In cases where mechanical fixtures are not feasible or where the electronic equipment 200 lacks compatible mounting interfaces, the adapter 100 may be affixed using one or more of adhesive tapes, hook-and-loop fasteners, and magnetically coupled mounting plates.

In certain implementations, the adapter 100 may further include one or more sealing elements positioned between the housing 102 and the front facia of the electronic equipment 200. Such sealing elements may include gaskets, compressible foam layers, elastomeric seals, or airflow shrouds configured to minimize bypass airflow around the housing 102. The sealing interface may ensure that substantially all intake air drawn by an inbuilt fan system of the electronic equipment 200 passes through one or more fluid conduits of the adapter 100 for effective thermal conditioning.

In one implementation, the adapter 100 may also be designed with one or more of adjustable brackets and universal mounting frames that can be aligned with a wide range of facia geometries, enabling compatibility across different makes and models of electronic equipment 200.

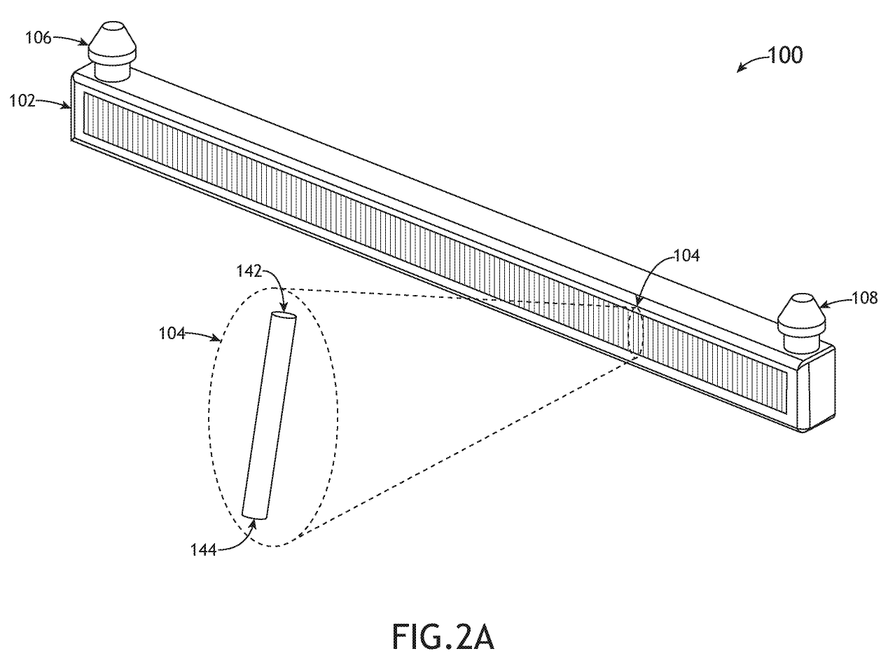

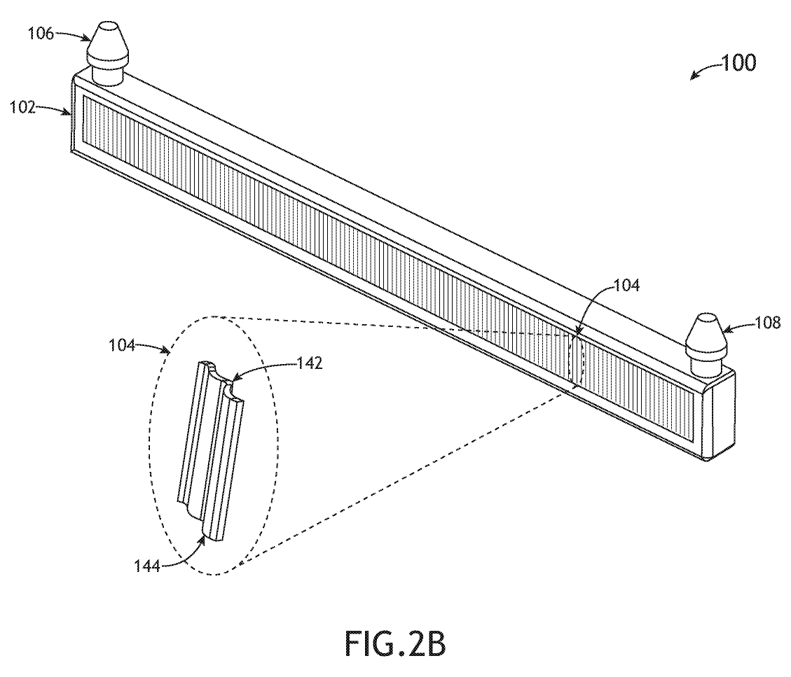

Now referring to FIGS. 2A and 2B, the adapter 100 may include a housing 102. The housing 102 may include an air intake region and an air outlet region, positioned opposite to each other. Further, the housing 102 may include one or more fluid conduits 104 positioned to form a mesh between the air intake region and the air outlet region of the housing 102.

In one illustrative implementation, the adapter 100 may have compact dimensions suitable for covering a single fan inlet of the electronic equipment 200. For example, the housing 102 may have dimensions of approximately 40 mm × 40 mm × 25 mm, with a single input port 106 and a single outlet port 108 to minimize piping complexity. The compact form factor enables the adapter 100 to be positioned directly over individual air vents 202 without obstructing adjacent components or interfering with rack-mounting configurations.

In the context of the present disclosure, “mesh” refers broadly to any structured or distributed arrangement of the one or more fluid conduits 104 that allows airflow to pass between and around the one or more fluid conduits 104 while facilitating heat exchange between the airflow and the cooling fluid. The mesh may include, but is not limited to, a grid arrangement, lattice configuration, staggered array, parallel array, cross-flow configuration, serpentine layout, matrix distribution, manifold-fed array, or any other structured conduit distribution that provides a distributed thermal interaction surface within the air passage. The conduits may be oriented vertically, horizontally, diagonally, or in mixed orientations depending on airflow direction and cooling requirements.

Shape of each of the fluid conduits 104 may be at least one of, a pipe structure (as shown in FIG. 2A) and a finned structure (as shown in FIG. 2B). The fluid conduits 104 may be hollow to facilitate cooling fluid flow therethrough, with the internal passages sized to balance fluid flow rate with heat transfer surface area. Each of the fluid conduits 104 may include a first opening 142 for cooling fluid inlet and a second opening 144 for cooling fluid outlet. Furthermore, the fluid conduits 104 may be interconnected with each other, via the housing 102. Selection between a finned structure and a pipe structure for the fluid conduits 104 within the adapter 100 depends on cooling requirements and design constraints of electronic equipment 200. A finned structure may offer a greater surface area for heat exchange between a cooling fluid inside the fluid conduits 104 and the intake air, which can result in more uniform cooling and enhanced thermal transfer efficiency across the adapter 100.

On the other hand, a pipe structure, particularly when densely packed, may facilitate higher flow rates of the cooling fluid and targeted thermal contact. Additionally, pipe-based designs may offer simpler manufacturability and maintenance in certain configurations. Accordingly, the adapter 100 may be implemented with either a pipe or a finned structure depending on thermal load, fluid type, spatial constraints, and airflow dynamics.

The one or more fluid conduits 104 may be formed from thermally conductive materials including, but not limited to, aluminum, copper, brass, stainless steel, thermally conductive polymers, composite materials, or combinations thereof. The one or more fluid conduits 104 may further include surface treatments or coatings such as corrosion-resistant coatings, dielectric coatings, anodized layers, or hydrophobic finishes to enhance durability, electrical isolation, or moisture management.

In various implementations, airflow through the housing 102 may interact with the fluid conduits 104 in different flow relationships, including axial flow, cross-flow, counter-flow, or co-flow configurations relative to the cooling fluid flowing within the conduits 104. The arrangement of the conduits 104 may be selected to promote laminar airflow for reduced pressure drop or to induce controlled turbulence to enhance convective heat transfer. The housing 102 may further include internal baffles, flow straighteners, or turbulence-inducing features to optimize heat exchange efficiency while maintaining acceptable airflow resistance.

Further, the adapter 100 may include at least one input port 106 to introduce the cooling fluid into the one or more fluid conduits 104 and at least one outlet port 108 to discharge the cooling fluid from the one or more fluid conduits 104. The cooling fluid absorbs heat from the airflow passing through the air intake region to the air outlet region of the housing 102. The cooling fluid may include but is not limited to, thermally conductive liquids such as water, glycol-based solutions, dielectric fluids, and refrigerants, as well as gases such as air, carbon dioxide, and inert gases like nitrogen.

In one implementation, the input port 106 and the outlet port 108 may be configured as pneumatic push-to-connect fittings, such as 4mm pneumatic couplers, to facilitate quick and tool-free connection and disconnection of fluid supply tubing. Such fittings may include a threaded base portion for secure attachment to the housing 102 and a release collar for rapid tubing engagement and disengagement, supporting ease of installation and maintenance of the cooling system.

Selection of the cooling fluid may depend on specific application requirements, including thermal conductivity, pressure and temperature tolerance, electrical insulation properties, environmental considerations, and compatibility with materials of the fluid conduits 104 and other components of the adapter 100.

In certain embodiments, where the cooling fluid reduces the intake air temperature below ambient dew point conditions, the adapter 100 may include condensation management features. Such features may include condensate collection channels, drainage passages, drip trays, moisture barriers, hydrophobic coatings on conduit surfaces, or insulated conduit sections to control moisture accumulation. These features may prevent liquid accumulation from entering the electronic equipment 200 while maintaining effective thermal conditioning of the intake air.

The input port 106 and the output port 108 may be coupled to a fluid circulation pump via a heat exchanger to enable continuous flow and thermal regulation of the cooling fluid through the one or more fluid conduits 104 within the adapter 100. The fluid circulation pump may be configured to maintain a predetermined flow rate and pressure to ensure effective heat transfer from the intake air to the cooling fluid. The fluid circulation pump may include, but is not limited to, a centrifugal pump, a diaphragm pump, a peristaltic pump, and a gear pump, depending on the nature of the cooling fluid, pressure and flow requirements for cooling the electronic equipment 200.

The heat exchanger may be operatively connected to the fluid circulation pump and may be positioned externally or remotely from the adapter 100. The heat exchanger may function to dissipate heat absorbed from the cooling fluid before it is recirculated back through the input port 106. The heat exchanger may include, but is not limited to, a finned radiator, forced-air unit, and liquid-to-liquid exchanger, depending on the cooling medium and space constraints.

In alternative implementations, circulation of the cooling fluid may be achieved through passive mechanisms, including thermosiphon circulation, gravity-assisted flow, phase-change loops, or other natural convection-based arrangements. In such implementations, the adapter 100 may operate without an active pump while still enabling heat absorption from the intake airflow.

The adapter 100 may be mountable on a front facia of the electronic equipment 200 having one or more air vents 202 (as shown in the FIG. 1A and 1B), reducing temperature of the airflow passing through the fluid conduits 104 in the housing 102 into the air vents 202 of the electronic equipment 200.

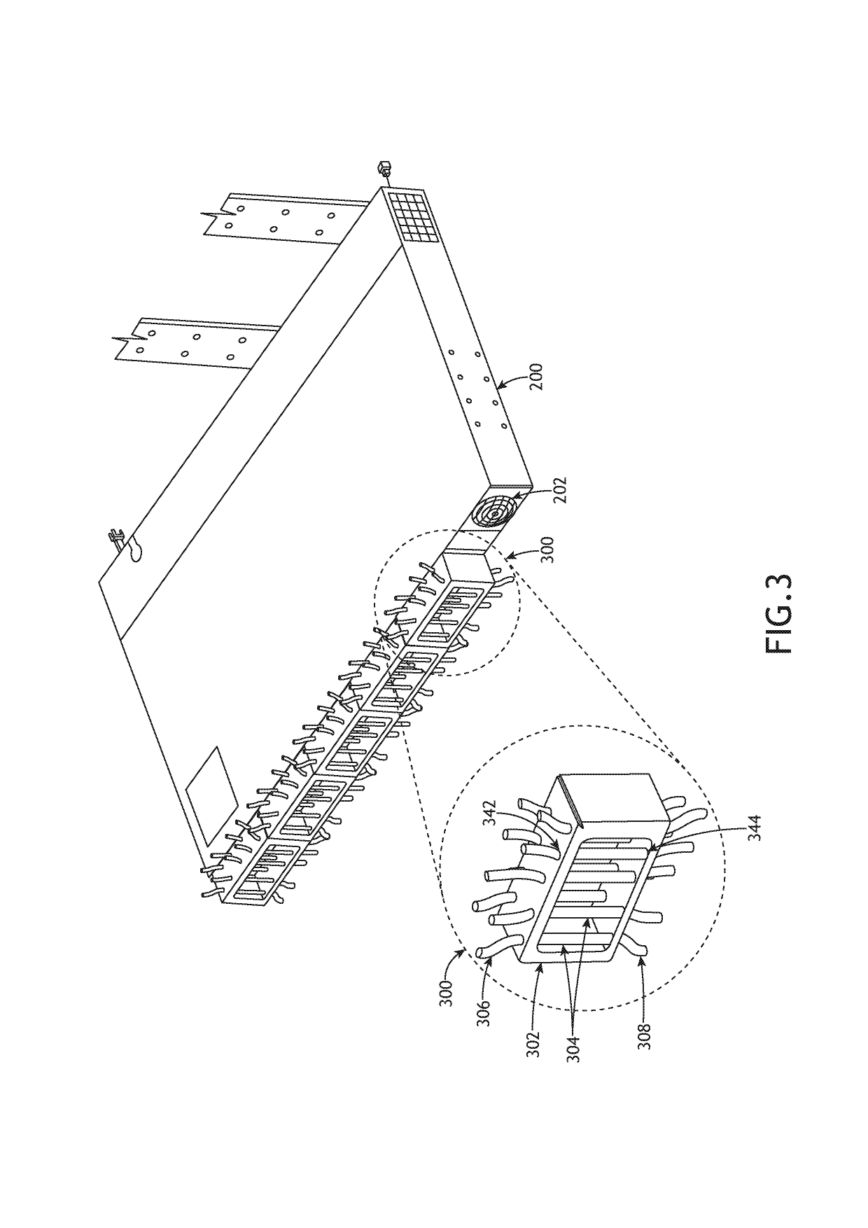

FIG. 3 illustrates an assembled view of the electronic equipment 200 and another adapter 300 for cooling the electronic equipment 200, and an expanded view of the adapter 300. The adapter 300 may be configured to absorb heat from the airflow being used to cool the electronic equipment 200. Thus, the adapter 300 may be applied to any equipment where conditioning the airflow can enhance thermal management, reduce internal hotspots, and improve performance and reliability of the electronic equipment 200.

One or more adapters 300 may be positioned externally with respect to the electronic equipment 200, such that each of the adapter 300 may align with each of the air vents 202 located on the front facia of the electronic equipment 200. Retro-fitting arrangement of the adapter 300 enables a modular integration with the electronic equipment 200 without requiring internal modifications to the electronic equipment 200.

The adapter 300 may be retrofitted to the electronic equipment 200 through a variety of attachment mechanisms, providing flexibility for integration across different equipment designs, form factors, and operational environments. The adapter 300 may include one or more snap-fit connectors that align with pre-existing slots, grooves, or anchoring features on the front facia of the electronic equipment 200. In one implementation, the adapter 300 may be fastened using one or more of spring-loaded screws, threaded bolts, and panel mount clips, allowing for a mechanically stable connection that can withstand vibration, movement, or exposure to dynamic airflow conditions. In cases where mechanical fixtures are not feasible or where the electronic equipment 200 lacks compatible mounting interfaces, the adapter 300 may be affixed using one or more of adhesive tapes, hook-and-loop fasteners, and magnetically coupled mounting plates.

In one implementation, the adapter 300 may also be designed with one or more of, adjustable brackets and universal mounting frames that can be aligned with a wide range of facia geometries, enabling compatibility across different makes and models of electronic equipment 200.

Further, as shown in FIG. 3, the adapter 300 may include a housing 302. The housing 302 may include an air intake region and an air outlet region, positioned opposite to each other. Further, one or more fluid conduits 304 may be positioned within the housing 302 to form a mesh between the air intake region and the air outlet region of the housing 302.

Shape of each of the fluid conduits 304 may be at least one of, a pipe structure (as shown in FIG. 3) and a finned structure (not shown in FIG. 3). Selection between a finned structure and a pipe structure for the fluid conduits 304 within the adapter 300 depends on cooling requirements and design constraints of electronic equipment 200. A finned structure may offer a greater surface area for heat exchange between a cooling fluid inside the fluid conduits 304 and the intake air, which can result in more uniform cooling and enhanced thermal transfer efficiency across the adapter 300.

On the other hand, a pipe structure, particularly when densely packed, may facilitate higher flow rates of the cooling fluid and targeted thermal contact. Additionally, pipe-based designs may offer simpler manufacturability and maintenance in certain configurations. Accordingly, the adapter 300 may be implemented with either a pipe or a finned structure depending on thermal load, fluid type, spatial constraints, and airflow dynamics.

The one or more fluid conduits 304 may be formed from thermally conductive materials including, but not limited to, aluminum, copper, brass, stainless steel, thermally conductive polymers, composite materials, or combinations thereof. The one or more fluid conduits 304 may further include surface treatments or coatings such as corrosion-resistant coatings, dielectric coatings, anodized layers, or hydrophobic finishes to enhance durability, electrical isolation, or moisture management.

Further, the fluid conduits 304 may be hollow. Furthermore, the fluid conduits 304 may be discrete and disconnected to each other. Each of the fluid conduits 304 may include a first opening 342 for cooling fluid inlet and a second opening 344 for cooling fluid outlet. Further, each first opening 342 may be connected to an input port 306 to receive the cooling fluid. Furthermore, each second opening 344 may be connected to an output port 308 to flush the cooling fluid after use.

The cooling fluid absorbs heat from the airflow passing through the air intake region to the air outlet region of the housing 302. The cooling fluid may include, but is not limited to, thermally conductive liquids such as water, glycol-based solutions, dielectric fluids, and refrigerants, as well as gases such as air, carbon dioxide, and inert gases like nitrogen. Selection of the cooling fluid may depend on specific application requirements, including thermal conductivity, pressure and temperature tolerance, electrical insulation properties, environmental considerations, and compatibility with materials of the fluid conduits 304 and other components of the adapter 300.

In certain embodiments, where the cooling fluid reduces the intake air temperature below ambient dew point conditions, the adapter 300 may include condensation management features. Such features may include condensate collection channels, drainage passages, drip trays, moisture barriers, hydrophobic coatings on conduit surfaces, or insulated conduit sections to control moisture accumulation. These features may prevent liquid accumulation from entering the electronic equipment 200 while maintaining effective thermal conditioning of the intake air.

The input port 306 and the output port 308 may be coupled to a fluid circulation pump via a heat exchanger to enable continuous flow and thermal regulation of the cooling fluid through the one or more fluid conduits 304 within the adapter 300. The fluid circulation pump may be configured to maintain a predetermined flow rate and pressure to ensure effective heat transfer from the intake air to the cooling fluid. The fluid circulation pump may include, but is not limited to, a centrifugal pump, a diaphragm pump, a peristaltic pump, and a gear pump, depending on the nature of the cooling fluid, pressure and flow requirements for cooling the electronic equipment 200.

The heat exchanger may be operatively connected to the fluid circulation pump and may be positioned externally or remotely from the adapter 300. The heat exchanger may function to dissipate heat absorbed from the cooling fluid before it is recirculated back through the input port 306. The heat exchanger may include, but is not limited to, a finned radiator, forced-air unit, and liquid-to-liquid exchanger, depending on the cooling medium and space constraints.

In alternative implementations, circulation of the cooling fluid may be achieved through passive mechanisms, including thermosiphon circulation, gravity-assisted flow, phase-change loops, or other natural convection-based arrangements. In such implementations, the adapter 300 may operate without an active pump while still enabling heat absorption from the intake airflow.

In certain implementations, the adapter 100 and the adapter 300 may further include one or more sensors configured to monitor parameters including intake air temperature, humidity, airflow rate, coolant temperature, or coolant flow rate. A controller may be operatively coupled to the fluid circulation pump to regulate coolant flow based on sensed operating conditions, thereby optimizing thermal performance while minimizing energy consumption.

In certain implementations, adapter 100 and adapter 300 represent alternative conduit architectures within the broader inventive concept. Adapter 100 may include interconnected fluid conduits 104 forming a continuous coolant distribution network within the housing 102, enabling shared coolant circulation across the conduit array. In contrast, adapter 300 may include discrete and mutually disconnected fluid conduits 304, each having independent inlet and outlet connections, thereby enabling separate coolant flow paths through individual conduits. Such architectural variations allow selection between distributed coolant equalization and independently controlled conduit cooling, depending on application requirements.

The methods, systems, devices, graphs, and/or tables discussed herein are examples. Various embodiments may omit, substitute, or add various procedures or components as appropriate. For instance, in alternative embodiments, the methods may be performed in an order different from that described, and/or various stages may be added, omitted, and/or combined. Also, features described with respect to certain embodiments may be combined in various other embodiments. Different aspects and elements of the embodiments may be combined in a similar manner. Also, technology evolves and, thus, many of the elements are examples and do not limit the scope of the disclosure or claims. Additionally, the techniques discussed herein may provide differing results with different types of context awareness classifiers.

Unless defined otherwise, all technical and scientific terms used herein have the same meaning as commonly or conventionally understood. As used herein, the articles “a” and “an” refer to one or to more than one (i.e., to at least one) of the grammatical object of the article. By way of example, “an element” means one element or more than one element. “About” and/or “approximately” as used herein when referring to a measurable value such as an amount, a temporal duration, and the like, encompasses variations of +20% or +10%, +5%, or +0.1% from the specified value, as such variations are appropriate to in the context of the systems, devices, circuits, methods, and other implementations described herein. “Substantially” as used herein when referring to a measurable value such as an amount, a temporal duration, a physical attribute (such as frequency), and the like, also encompasses variations of ±20% or ±10%, ±5%, or ±0.1% from the specified value, as such variations are appropriate to in the context of the systems, devices, circuits, methods, and other implementations described herein.

As used herein, including in the claims, “and” as used in a list of items prefaced by “at least one of” or “one or more of” indicates that any combination of the listed items may be used. For example, a list of “at least one of A, B, and C” includes any of the combinations A or B or C or AB or AC or BC and/or ABC (i.e., A and B and C). Furthermore, to the extent more than one occurrence or use of the items A, B, or C is possible, multiple uses of A, B, and/or C may form part of the contemplated combinations. For example, a list of “at least one of A, B, and C” may also include AA, AAB, AAA, BB, etc.

While illustrative and presently preferred embodiments of the disclosed systems, methods, and/or machine-readable media have been described in detail herein, it is to be understood that the inventive concepts may be otherwise variously embodied and employed, and that the appended claims are intended to be construed to include such variations, except as limited by the prior art. While the principles of the disclosure have been described above in connection with specific apparatuses and methods, it is to be clearly understood that this description is made only by way of example and not as a limitation on the scope of the disclosure.

What is claimed is:

1. An adapter for an electronic equipment, comprising:
a housing having an air intake region and an air outlet region, the housing comprises one or more fluid conduits positioned to form a mesh between the air intake region and the air outlet region;
at least one input port to introduce cooling fluid into the one or more fluid conduits and at least one outlet port to discharge the cooling fluid from the one or more fluid conduits,
wherein the cooling fluid absorbs heat from air passing through the air intake region to the air outlet region of the housing; and
wherein the adapter is mountable on a front facia of the electronic equipment having one or more air vents, reducing temperature of the air passing through the air intake region and air outlet region of the housing into the air vents of the electronic equipment.

2. The adapter of claim 1, wherein each of the fluid conduits includes a first opening for fluid inlet and a second opening for fluid outlet.

3. The adapter of claim 1, wherein the one or more fluid conduits are interconnected with each other to form a continuous fluid path between the air intake region and the air outlet region of the housing.

4. The adapter of claim 1, wherein the one or more fluid conduits are selected from a group including at least one of: a pipe structure, and a finned structure, wherein the finned structure provides an increased surface area for heat exchange between the cooling fluid and the air passing through the air intake region to the air outlet region of the housing.

5. The adapter of claim 1, wherein each of the one or more fluid conduits is discrete and independently connected to the input port and the outlet port to provide separate coolant flow paths.

6. The adapter of claim 1, wherein the input port and the outlet port are coupled to a fluid circulation pump via a heat exchanger.

7. The adapter of claim 1, wherein the housing comprises at least one airflow directing element selected from baffles, flow straighteners, or turbulence-inducing features configured to enhance convective heat transfer.

8. The adapter of claim 1, further comprising at least one sealing element positioned between the housing and the front facia of the electronic equipment to reduce bypass airflow around the housing.

9. The adapter of claim 1, wherein the one or more fluid conduits are formed from thermally conductive materials including at least one of aluminum, copper, stainless steel, thermally conductive polymer, or composite material.

10. The adapter of claim 1, further comprising one or more sensors configured to monitor at least one parameter selected from intake air temperature, humidity, airflow rate, coolant temperature, or coolant flow rate.

11. The adapter of claim 10, further comprising a controller operatively coupled to a fluid circulation pump to regulate coolant flow based on sensed operating conditions.

12. A cooling system for an electronic equipment, comprising:
electronic equipment having an enclosure with one or more air vents on a front facia and at least one inbuilt fan system configured to draw air through the one or more air vents; and
an adapter mounted on the front facia of the electronic equipment, the adapter comprising:
a housing having an air intake region and an air outlet region aligned with the one or more air vents, the housing comprising one or more fluid conduits positioned to form a mesh between the air intake region and the air outlet region;
at least one input port to introduce cooling fluid into the one or more fluid conduits and at least one outlet port to discharge the cooling fluid from the one or more fluid conduits; and
wherein the cooling fluid absorbs heat from air passing through the air intake region to the air outlet region of the housing before the air enters the one or more air vents of the electronic equipment.

13. The cooling system of claim 12, further comprising a fluid circulation pump coupled to the input port and the outlet port to circulate the cooling fluid through the one or more fluid conduits.

14. The cooling system of claim 13, further comprising a heat exchanger operatively connected to the fluid circulation pump and configured to dissipate heat absorbed by the cooling fluid.

15. The cooling system of claim 12, wherein the adapter further comprises condensation management features including at least one of condensate collection channels, drainage passages, drip trays, moisture barriers, or hydrophobic coatings on conduit surfaces.

16. A method of cooling electronic equipment, comprising:
mounting an adapter on a front facia of the electronic equipment, the adapter comprising a housing having an air intake region and an air outlet region aligned with one or more air vents of the electronic equipment, the housing comprising one or more fluid conduits positioned to form a mesh between the air intake region and the air outlet region;
circulating a cooling fluid through the one or more fluid conduits via at least one input port and at least one outlet port of the adapter;
drawing air through the air intake region of the housing using an inbuilt fan system of the electronic equipment; and
absorbing heat from the air passing through the air intake region to the air outlet region of the housing using the cooling fluid, thereby reducing temperature of the air before the air enters the one or more air vents of the electronic equipment.

17. The method of claim 16, further comprising circulating the cooling fluid using a fluid circulation pump selected from a centrifugal pump, a diaphragm pump, a peristaltic pump, or a gear pump.

18. The method of claim 16, further comprising dissipating heat absorbed by the cooling fluid using a heat exchanger selected from a finned radiator, a forced-air unit, or a liquid-to-liquid exchanger.

19. The method of claim 16, wherein the cooling fluid comprises at least one of water, a glycol-based solution, a dielectric fluid, or a refrigerant.

20. The method of claim 16, further comprising attaching the adapter to the front facia of the electronic equipment using at least one attachment mechanism selected from snap-fit connectors, spring-loaded screws, threaded bolts, panel mount clips, adhesive tapes, hook-and-loop fasteners, or magnetically coupled mounting plates.
